(19) United States
(12) Patent Application Publication
(10) Pub. No.: US 2020/0295541 A1
(43) Pub. Date: Sep. 17, 2020

(54) RESETTABLE RELAY CONTROL FOR MICRO POWER DISTRIBUTION BLOCKS

(71) Applicant: Molex, LLC, Lisle, IL (US)

(72) Inventors: David E. DUNHAM, Metamora, MI (US); Rand WILBURN, Noblesville, IN (US)

(73) Assignee: Molex, LLC, Lisle, IL (US)

(21) Appl. No.: 16/767,607

(22) PCT Filed: Dec. 3, 2018
(86) PCT No.: PCT/US18/63588

§ 371 Date: May 28, 2020

Related U.S. Application Data
(60) Provisional application No. 62/594,094, filed on Dec. 4, 2017.

(51) Int. Cl. H02B 1/04; H02B 1/26; H02B 1/24; H03K 3/037

(52) U.S. Cl. CPC H02B 1/04; H03K 3/037; H02B 1/24; H02B 1/26

(57) ABSTRACT

A micro power distribution block comprises: an enclosure; a connector, the connector comprising a power input terminal, a power output terminal, a ground terminal, and a reset terminal; and a circuit member disposed within the enclosure and operatively connected to the connector. The circuit member includes a relay coupled to the power input terminal. The relay is configured to switch between an ON state and an OFF state. The circuit member also includes a feedback sensor configured to sense power flow through the relay in the ON state. The circuit member further includes a control circuit configured to: (a) generate a relay control signal for switching the relay from the ON state to the OFF state based on a magnitude of the sensed power flow, and (b) receive a reset signal, via the reset terminal, for switching the relay from the OFF state to the ON state.

### CROSS-REFERENCE TO RELATED APPLICATIONS

This patent application claims the benefit of U.S. Provisional Patent Application No. 62/594,094, filed Dec. 4, 2017, which is incorporated by reference.

### BACKGROUND

Power distribution blocks are provided in electricity supply systems that take an electrical power feed and distributes the feed to subsidiary circuits, while providing a protective fuse for the subsidiary circuits in a common enclosure. The fuse serves as an overcurrent protection when current provided via a power distribution block exceeds a limit. Power distribution blocks are used in various applications and come in different current ratings. The current ratings specify a maximum total current draw that the power distribution block can handle before its fuse blows.

### SUMMARY

Embodiments of the disclosure provide a micro power distribution block for operation in a high temperature environment. The micro power distribution block includes: an enclosure; a connector, the connector comprising a power input terminal, a power output terminal, a ground terminal, and a reset terminal; and a circuit member disposed within the enclosure and operatively connected to the connector. The circuit member includes: a relay coupled to the power input terminal, the relay configured to switch between an ON state and an OFF state, wherein the relay allows power flow from the power input terminal through the relay in the ON state and prevents power flow from the power input terminal through the relay in the OFF state; a feedback sensor configured to sense power flow through the relay in the ON state; and a control circuit configured to: (a) generate a relay control signal for switching the relay from the ON state to the OFF state based on a magnitude of the sensed power flow, and (b) receive a reset signal, via the reset terminal, for switching the relay from the OFF state to the ON state.

Embodiments of the disclosure provide a method for distributing power to a load by a micro power distribution block comprising: (a) receiving a power input via a connector of the micro power distribution block, the power input received via a power input terminal of the connector and powering a circuit member of the micro power distribution block; (b) sensing, via a feedback sensor of the circuit member, power flow from the power input terminal through a relay of the circuit member; (c) determining, via a control circuit of the circuit member, whether a magnitude of the sensed power flow exceeds a power threshold; (d) in response to said determining that the power threshold is exceeded, generating, by the control circuit, a relay control signal for switching the relay from the ON state to the OFF state; (e) receiving a reset signal via the connector, the reset signal received via a reset terminal of the connector; and (f) in response to receiving the reset signal, switching, via the control circuit, the relay from the OFF state to the ON state, wherein the relay allows power flow from the power input terminal through the relay in the ON state and prevents power flow from the power input terminal through the relay in the OFF state.

### BRIEF DESCRIPTION OF THE DRAWINGS

FIG. 1 is a micro power distribution block (μPDB) according to an embodiment of the disclosure;

FIG. 2 is a block diagram illustrating components in a μPDB according to an embodiment of the disclosure;

FIG. 3 is a schematic of a μPDB according to an embodiment of the disclosure;

FIG. 4 is a printed circuit board layout of a IμPDB according to an embodiment of the disclosure; and

FIG. 5 is a flow diagram for operating a μPDB according to an embodiment of the disclosure.

### DETAILED DESCRIPTION

The present disclosure generally relates to an electrical relay controls and, more specifically, to a settable field effect transistor-based relay typically used in a vehicle. In general, relays of this type are suitable for use in vehicle systems including junction distribution blocks, power distribution modules (PDM) or power distribution blocks (PDB), and other body control systems. These systems typically employ a wire harness to connect the various body and control systems throughout the vehicle. Without loss of generality, micro power distribution blocks will be used in describing various embodiments of the disclosure.

Power distribution blocks (PDB) are enclosures or boxes that typically contain fuses and relays. Conventional PDBs are designed for specific current ratings demanded by specific applications. Each application requires the selection of a specific type or size of fuse to use in the sealed box. Selecting a desired fuse size for the application limits applicability of a manufactured PDB. For example, a PDB having a current rating of 20 A cannot be used in an application requiring a current rating of 60 A, so when an application's specification changes, the PDB may have to be replaced to meet the new specification. Furthermore, during use, once a fuse blows, the blown fuse must be replaced. Still further, fuses and fuse terminals may add a significant amount of heat to a PDB design, thus limiting how much current each unit can carry as well as acceptable physical locations of the PDB in an application.

Embodiments of the disclosure provide a sealed micro power distribution block (μPDB) with a resettable relay. The resettable relay allows resetting of the μPDB once the current limit is reached. Compared to conventional PDBs, the sealed μPDB with the resettable relay does not have a fuse, so once reset, the sealed μPDB can be reused. Furthermore, the resettable relay of the μPDB can be programmed for use in various applications since a desired fuse size is not hardware dependent. One μPDB design can be used for various applications and a programmed current rating can determine when the relay trips, preventing power from being supplied to downstream electrical loads. Further, a μPDB programmed for an application requiring a current rating of 20 A can be repurposed for use in an application requiring 60 A by reprogramming it for 60 A.

Embodiments of the disclosure provide a sealed μPDB that is programmable for various current limits. An advantage of the programmable sealed μPDB design is that it reduces required inventory and changes in printed circuit board layouts. The same sealed μPDB design can be used in various applications requiring different current ratings, thus there is no need for an organization or user to maintain multiple sealed μPDB designs, each having different fuse ratings.

A sealed μPDB can be used in harsh environments like an automobile's engine compartment. The engine compartment can get very hot, reaching temperatures of from −40° C. to 110° C. As such, opening a sealed μPDB to replace a fuse may be impractical since tampering with the sealing element of the μPDB can compromise its quality, rendering the iμPDB unable to fully protect its electronics from environmental elements. Furthermore, even if the fuse were to be replaced, it would require replacing the blown fuse and resealing the μPDB. Sealed μPDBs are typically discarded and replaced once their fuses blow. Embodiments of the disclosure provide an alternative to the options of discarding the sealed μPDB or replacing the fuse within the sealed uPDB by providing a resettable sealed μPDB that can be programmed for various current ratings. A design for a resettable sealed μPDB which is programmable can be scaled to various applications, and once a current limit is reached, the same sealed μPDB can be reset and reused without the need to tamper with the protective covering and seals of the sealed μPDB. The cost associated with using a resettable μPDB is less than the cost of replacing a sealed μPDB or replacing a fuse within the sealed μPDB. Sealed μPDBs according to embodiments of the disclosure operate within a temp range of −40° C. to 110° C., in wet or dry environments, and in many automotive vibration environments. They are resistive to typical chemicals found in the automotive environments.

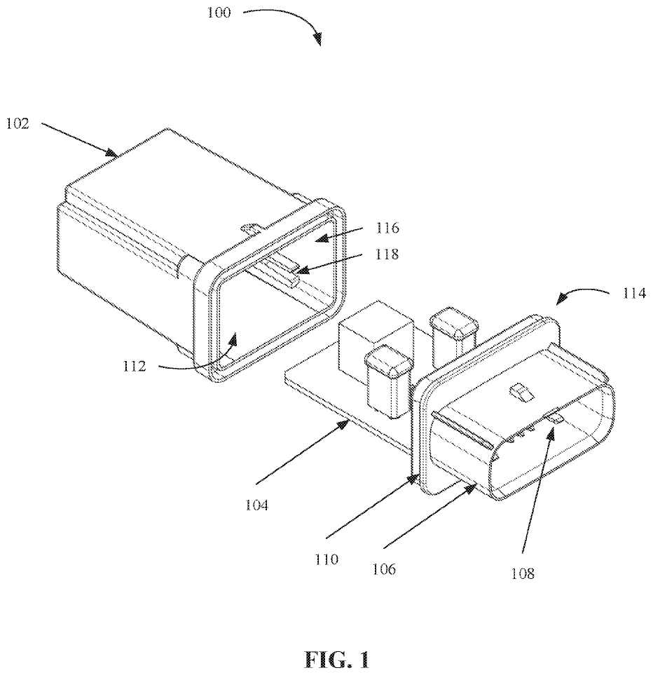

FIG. 1 illustrates a μPDB 100 for operation in a high temperature environment according to an embodiment of the disclosure. The PDB 100 includes a rear cover 102, a circuit member such as a printed circuit board (PCB) 104, and an interconnect component such as connector 114. The rear cover 102 has a cavity 112 with an opening for receiving the PCB 104. In some embodiments, the rear cover 102 can include channels or slots 118 along sidewalls 116 of the rear cover 102 that are configured to slidingly receive, support, and secure the PCB 104 within the rear cover 102. Other manners of mounting the PCB 104 within the rear cover 102 are contemplated.

The connector 114 includes a flange 110 with a shroud 106 extending therefrom. A plurality of electrically conductive terminals or contacts 108 are mounted on the connector 114 with a mating end of each terminal disposed within the shroud 106. Mounting ends (not shown) of each terminal 108 are electrically connected to the PCB 104.

The flange 110 is configured in a manner that substantially matches the opening of the rear cover 102 such that the rear cover 102 and the flange 110 define an enclosure that can be readily sealed. In an embodiment, an adhesive or glue may be applied between the rear cover 102 and the shroud 106. Further, the terminals 108 may extend through the connector 114 in a sealed manner so that the PCB 104 is fully sealed within the enclosure formed by the combination of the rear cover 102 and flange 110 to prevent liquids or other substances from reaching the electronic components and circuitry within the cavity. Electrical connections to the PCB 104 are provided via the mating portions of the terminals 108 disposed within the shroud 106. Examples of materials used in μPDBs according to embodiments of the disclosure include plastic materials such as polybutylene terephthalate (PBT). PCB 104 can be made with high temperature FR4 materials. In an embodiment, the adhesive includes a sealant that bods two plastic components.

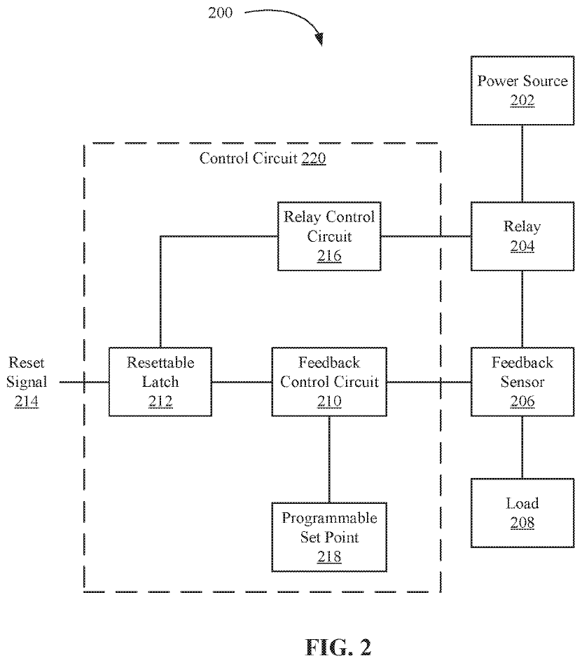

FIG. 2 is a block diagram illustrating components associated with a PCB 200 of a μPDB according to an embodiment of the disclosure. FIG. 2 illustrates components mounted on or disposed in, e.g., PCB 104. The PCB 200 can include access to a power source 202. Access to the power source 202 can be provided via terminals of a connector, e.g., the connector 114. The terminals for access to the power source 202 may be a power input terminal and a ground terminal.

The PCB 200 further includes a relay 204 coupled to the power source 202. The relay 204 switches between an ON state and an OFF state. The relay 204 allows power flow from the power source 202 through the relay 204 in the ON state and prevents power flow from the power input terminal through the relay 204 in the OFF state. Examples of relay 204 include single pole single throw (SPST), single pole double throw (SPDT), H bridge, and twin relays. Attachment methods may include thru hole and SMT design.

The PCB 200 further includes a feedback sensor 206 that senses power flow through the relay 204 in the ON state. The feedback sensor 206 essentially senses power flow through the relay 204 to the load 208. Access to the load 208 can be provided via a power output terminal of the connector. The feedback sensor 206 can sense a current flowing through the relay 204 and/or a voltage drop across its terminals and provide the sensed current flow or the voltage drop a measure of the power flow through the relay 204 since power is directly proportional to both voltage and current. The feedback sensor 206 can be an electrical, thermal or optical sensor that sends a feedback signal to a control circuit 220 for switching states of the relay 204.

The PCB 200 further includes the control circuit 220 for switching the relay 204 between the ON state and the OFF state. In an embodiment, the control circuit is a microcontroller or a microprocessor that receives a reset signal 214 and/or a magnitude of the sensed power flow from the feedback sensor 206 and generates a relay control signal for switching the relay 204 between the ON state and the OFF state. The relay control signal switches the relay 204 from the ON state to the OFF state when the magnitude of the sensed power flow exceeds a target threshold. The relay control signal switches the relay 204 from the OFF state to the ON state when the reset signal 214 is asserted.

In an embodiment where the control circuit includes a microcontroller or a microprocessor, the control signal can generate an error code whenever the relay 204 switches from the ON state to the OFF state. The microcontroller may be a local interconnect network (LIN) chip or a control area network (CAN) chip in an automobile or in an automotive environment. The LIN or CAN chip can provide the error code to other systems in the automobile whenever the relay 204 switches to the OFF state.

In an embodiment, the control circuit 220 for switching the relay 204 includes a programmable set point 218, a feedback control circuit 210, a resettable latch 212, and a relay control circuit 216. The programmable set point 218 can be a resistor ladder controlled via switches for generating a target threshold voltage as the target threshold. The programmable set point 218 can be set of current sources combined via switches for generating a target threshold current as the target threshold. The programmable set point 218 can be a microcontroller with a digital to analog converter for providing the target threshold directly to the feedback control circuit 210.

The feedback control circuit 210 compares the sensed power flow from the feedback sensor 206 and the target threshold from the programmable set point 218 to determine whether the sensed power flow exceeds the target threshold. The feedback control circuit 210 generates an OFF signal for turning OFF the relay when the target threshold is exceeded.

The resettable latch 212 latches the OFF signal and provides the latched OFF signal to the relay control circuit 216. The relay control circuit 216 generates the relay control signal for switching the relay 204 from the ON state to the OFF state based on receiving the latched OFF signal from the latch 212.

After the relay 204 is in the OFF state, the conditions that generated the OFF signal in the feedback control circuit 210 are no longer present, and the feedback sensor 206 senses zero current. The OFF signal from the feedback control circuit 210 is no longer asserted when zero current is flowing through the relay 204, but the resettable latch 212 still has an asserted latched OFF signal, so the relay 204 will remain in the OFF state. The reset signal 214, when asserted, resets the latch 212 so that the latched OFF signal is de-asserted. Once the latch 212 is reset, the relay control circuit 216 generates the relay control signal for switching the relay 204 from the OFF state to the ON state.

In some embodiments, the relay 204 and the relay control circuit 216 can be replaced with a FET. The FET can receive from the resettable latch 212 control signal for switching from an ON state to an OFF state and vice versa. In the OFF state, the FET operates in a similar manner as a relay, preventing power flow to the load 208, and in the ON state, the FET allows power flow to the load 208.

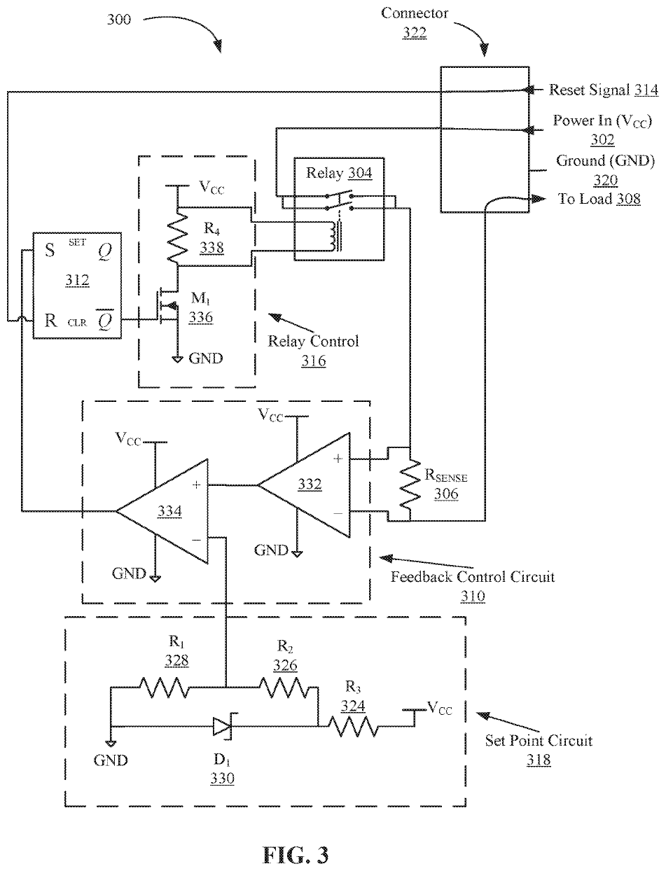

FIG. 3 is a schematic of a PCB 300 of a μPDB according to an embodiment of the disclosure. FIG. 3 illustrates a schematic of, e.g., the PCB 104. The PCB 300 can include a connector 322 for input/output communication and also for power access and provision. The connector 322 serves to electrically connect the PCB to other electrical components outside the PCB. The connector 322 can provide terminals for, e.g., a reset signal 314, a power in (V_{CC}) 302, a ground (GND) 320, and a power out to a load 308. In some embodiments, the connector 322 provides a signal for programming a target threshold for the control circuitry.

The PCB 300 can include a relay 304, which is an example of the relay 204. The relay 304 can be modeled as a double pole single throw (DPST) switch controlled by a magnetic coil. When current flows through the magnetic coil, the DPST switch (hence the relay 304) is in an ON state, allowing power flow from the power in 302 terminal to circuit components downstream. When current does not flow through the magnetic coil, the DPST switch (hence the relay 304) is in an OFF state, preventing power flow from the power in 302 terminal to the circuit components downstream.

The PCB 300 can include a resistor R_{SENSE} 306 for sensing a current flow through the relay 304. The R_{SENSE} 306 is an example of the feedback sensor 206. The R_{SENSE} 306 is connected between the relay 304 and the power out to the load 308, thus current flow through the R_{SENSE} 306 is the current supplied to the load.

The feedback control circuit 310 is included in the PCB 300. The feedback control circuit 310 includes a feedback amplifier 332 and a comparator 334. The feedback amplifier 332 determines a magnitude of a voltage difference across R_{SENSE} 306 and amplifies this magnitude. In an embodiment, the feedback amplifier 332 is a difference amplifier that is temperature stable. The comparator 334 compares the amplified magnitude with the target threshold to determine whether the target threshold is exceeded by the amplified magnitude.

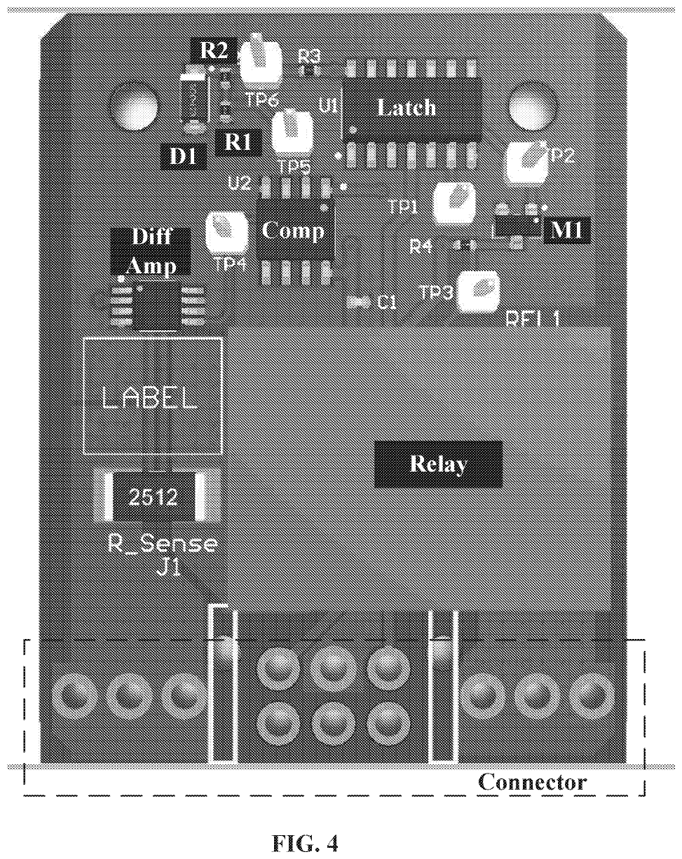

In an embodiment, the target threshold is generated by a set point circuit 318 which includes a resistive divider including resistors R₁ 328, R₂ 326, R₃ 324 and a Zener diode D₁ 330. R₃ 324 serves a protective role, bearing an excess voltage drop between V_{CC} and the voltage drop across D₁ 330. D₁ 330 provides a stable voltage across the series combination of R₁ 328 and R₂ 326. R₁ 328 and R₂ 326 implement a voltage divider such that the target threshold is a voltage drop across R₁ 328. Table 1 shows different R₁ 328 and R₂ 326 combinations for setting different target thresholds in an example design using the PCB layout of FIG. 4. In an embodiment, D₁ 330 is automotive grade and temperature stable.

TABLE 1

| | | | | Current | | |
|---|---|---|---|---|---|---|
| | Current | mv out | Vₒᵤₜ | for | R₁ | |
| Combination | Output | (TP4) | (TP1) | R₁&R₂ | (Ohms) | R₂(Ohms) |
| 1 | 20 | 20 | 1.01 | 0.506 mA | 2k | 8.06k |
| 2 | 30 | 30 | 1.53 | 0.511 mA | 3k | 6.98k |
| 3 | 40 | 40 | 2.04 | 0.508 mA | 4.02k | 6.04k |
| 4 | 50 | 50 | 2.53 | 0.511 mA | 4.99k | 4.99k |
| 5 | 60 | 60 | 3.04 | 0.508 mA | 6.04k | 4.02k |

The comparator 334 of the feedback control circuit 310 determines whether the amplified voltage across R_{SENSE} 306 exceeds the target threshold, and when it does, then the comparator 334 asserts a relay control signal for switching the relay 304 to the OFF state. The relay control signal, when asserted, is latched by the latch 312. In the example provided in Table 1, the resistance values of R1 and R2 (R₁ 328 and R₂ 326) are chosen to determine the target threshold. The voltage (TP4) is the voltage across R_{SENSE} 306, and the voltage across R₁ (TP1) is the voltage presented at the input of the comparator 334. The voltage (TP1) indicates the target threshold, and when the voltage (TP4) is amplified and compared, the relay control signal is asserted once the target threshold is reached. In Table 1, it can be inferred that the feedback amplifier 332 provides a 50X gain to the voltage (TP4) across R_{SENSE} 306.

In an embodiment, the latch 312 is an S-R latch with an S input, an R input, a Q output, and a Q-bar output. When both the S input and the R input are de-asserted, the S-R latch is in a hold state; when the S input is asserted, the S-R latch is in a set state, and when the R input is asserted, the S-R latch is in a reset state. By asserting the relay control signal connected to the S input of the S-R latch, the S input is asserted while the R input is de-asserted, thus the latch 312 is in a set state.

The Q-bar output of the S-R latch controls a relay control circuit 316. The relay control circuit 316 includes a transistor M₁ 336 that is either in an ON transistor state or an OFF transistor state based on the Q-bar output. When the latch 312 is in the set state, then Q-bar output controls M₁ 336 to switch to an OFF transistor state, disabling current flow through M₁ 336. The lack of current flow through M₁ 336 results in no voltage drop across resistor R₄ 338, which indicates no voltage difference applied to the magnetic coils of the relay 304 and, therefore, the relay 304 switches from the ON state to the OFF state.

When the relay 304 is in the OFF state, R_{SENSE} 306 no longer has current flowing through it which causes the amplifier 332 to provide an amplified voltage substantially lower than the target threshold. Therefore, the comparator 334 de-asserts the relay control signal and the S-R latch then has an input combination where both the S and R inputs are de-asserted, placing the S-R latch in a hold state. That is, although the relay control signal is de-asserted, the S-R latch maintains the previous Q-bar output, therefore, M₁ 336 remains in an OFF transistor state and the relay 304 remains in an OFF state.

M₁ 336 can be placed in the ON transistor state, enabling current flow through M₁ 336, by asserting the reset signal 314. The reset signal 314 is an input to the R input of the S-R latch, thus when the R input is asserted, the S-R latch is reset, and the Q-bar output controls M₁ 336 to switch to the ON transistor state. In the ON transistor state, there is a current flow through R₄ 338, thus a voltage difference provided to the magnetic coil of the relay 304, and the relay 304 switches from the OFF state to the ON state. After some time, the reset signal 314 is de-asserted, so both the S and R inputs of the S-R latch are de-asserted, putting the S-R latch in a hold state.

Although described with an S-R latch, other types of latches can be used, e.g., a J-K latch. The Q-bar output of the S-R latch is used for controlling the M₁ 336, but based on transistor type or logic circuit, the Q output may be used in other embodiments. The M₁ 336 can be a p-type field effect transistor (FET) or an n-type FET, and an enhancement mode FET or a depletion mode FET. R_{SENSE} 306 is chosen to be as small as possible.

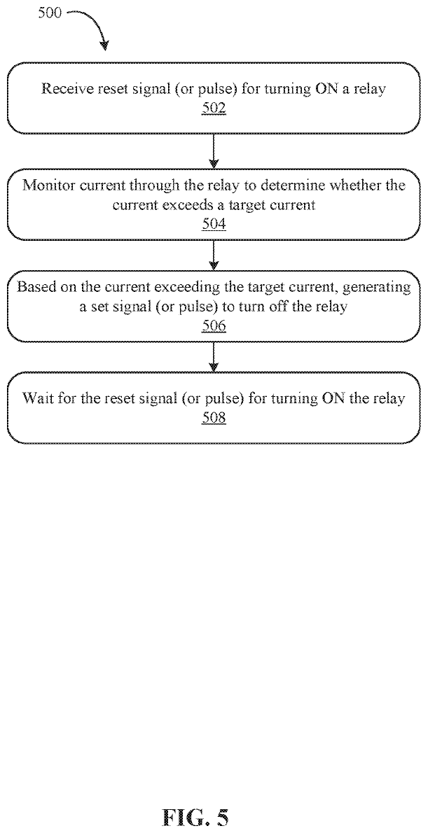

FIG. 5 is a flow diagram 500 for operating a PCB of a PDB according to an embodiment of the disclosure. At 502, the PCB receives a reset signal for turning ON a relay. The reset signal is asserted then de-asserted, thus can be viewed as a reset pulse.

At 504, the PCB monitors current through the relay to determine whether the current exceeds a target current threshold. The target current threshold can be programmable to indicate a maximum tolerable current allowed to flow through the relay. The PCB monitors the current via a feedback sensor according to embodiments of the disclosure.

At 506, when the current flowing through the relay exceeds the target current threshold, the PCB generates a set signal to turn OFF the relay. Once the relay is turned OFF, the set signal is de-asserted, but the relay remains in the OFF state. This behavior can be achieved with a latch that captures the set signal being asserted and turns OFF the relay based on the set signal being asserted.

At 508, the PCB waits for the reset signal or pulse in order to turn ON the relay. That is, once the set signal is latched, causing the relay to turn OFF, the reset signal is the only signal that can turn the relay back ON.

Embodiments of the disclosure provide a PDB with a resettable power relay. The resettable relay can trip at various reset points, e.g., between the range of 10 A to 40 A. The μPDB can be reset by cycling the power provided to components on the PCB of the μPDB or by toggling a reset signal input of the PCB. The μPDB exhibits high thermal performance via high current relays, sturdy PCB materials and terminal/connector designs. The μPDB is sealed to an IP67K rating, thus providing protection against environmental factors such as liquids and solids. The μPDB can vary input voltage from 7 V to 14 V with little to no effect on control electronics, thus making the μPDB compatible with automotive applications. A FET control in relay coil path relaxes thermal or high current requirements.

Embodiments of the disclosure provide a μPDB that can be used for automotive applications. μPDBs utilized in the automotive world must pass various environmental tests. Load conditions, i.e., resistive, capacitive or inductive, vibration testing under elevated temperatures, humidity, salt spray, thermal shock, current and voltage cycling, are requirements for functional performance of μPDBs. Due to potential high currents, good contact interface design, in a sealed environment, are necessary. Because of the electronic components, electromagnetic compatibility (EMC) requirements are also necessary. Embodiments of the disclosure provide advantages within harsh automotive environments by using a feedback loop to sense current provided to electric loads and stop the current flow when a limit is reached. Current flow is prevented until a reset signal is received by the μPDB, therefore, the μPDB does not toggle back and forth between an ON and OFF states due to the feedback loop.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A micro power distribution block for operation in a high temperature environment comprising:
an enclosure;
a connector, the connector comprising a power input terminal, a power output terminal, a ground terminal, and a reset terminal; and
a circuit member disposed within the enclosure and operatively connected to the connector, the circuit member comprising:
a relay coupled to the power input terminal, the relay configured to switch between an ON state and an OFF state, wherein the relay allows power flow from the power input terminal through the relay in the ON state and prevents power flow from the power input terminal through the relay in the OFF state,
a feedback sensor configured to sense power flow through the relay in the ON state, and
a control circuit configured to: (a) generate a relay control signal for switching the relay from the ON state to the OFF state based on a magnitude of the sensed power flow, and (b) receive a reset signal, via the reset terminal, for switching the relay from the OFF state to the ON state.

2. The micro power distribution block according to claim 1, wherein the connector includes a flange configured to sealingly engage the enclosure.

3. The micro power distribution block according to claim 1, wherein a first portion of the connector is disposed within the enclosure and a second portion of the connector extends from the enclosure.

4. The micro power distribution block according to claim 1, wherein the control circuit comprises:
a feedback control circuit configured to: (a) receive the magnitude of the sensed power flow from the feedback sensor, (b) amplify the magnitude of the sensed power flow, (c) determine whether the amplified magnitude of the sensed power flow exceeds a target power threshold, and (d) generate the relay control signal based on the amplified magnitude of the sensed power flow exceeding the target power threshold;
a latch configured to: (a) latch the relay control signal based on the amplified magnitude of the sensed power flow exceeding the target power threshold, and (b) latch the reset signal from the reset terminal;
a relay control circuit configured to: (a) switch the relay to the OFF state based on the latched relay control signal, and (b) switch the relay to the ON state based on the reset signal.

5. The micro power distribution block according to claim 2, wherein the target power threshold is programmable.

6. The micro power distribution block according to claim 2, wherein the target power threshold is determined via a set point circuit comprising a resistive divider.

7. The micro power distribution block according to claim 2, wherein:
the feedback sensor is a resistor; and
the sensed power flow comprises: (a) a sensed current flowing through the resistor, and/or (b) a sensed voltage drop across the resistor.

8. The micro power distribution block according to claim 2, wherein the latch comprises an S-R latch and/or a J-K latch.

9. The micro power distribution block according to claim 2, wherein the relay control circuit comprises:
a transistor configured to provide a relay coil control signal, the relay coil control signal switching the relay from: (a) an ON state to an OFF state based on the latched relay control signal, and (b) from an OFF state to an ON state based on the reset signal.

10. The micro power distribution block according to claim 1, wherein the control circuit is a microcontroller or a microprocessor.

11. The micro power distribution block according to claim 10, wherein the control circuit provides an error code when the relay switches from the ON state to the OFF state.

12. A method for distributing power to a load by a micro power distribution block comprising:
receiving a power input via a connector of the micro power distribution block, the power input received via a power input terminal of the connector and powering a circuit member of the micro power distribution block;
sensing, via a feedback sensor of the circuit member, power flow from the power input terminal through a relay of the circuit member;
determining, via a control circuit of the circuit member, whether a magnitude of the sensed power flow exceeds a power threshold;
in response to said determining that the power threshold is exceeded, generating, by the control circuit, a relay control signal for switching the relay from the ON state to the OFF state;
receiving a reset signal via the connector, the reset signal received via a reset terminal of the connector; and
in response to receiving the reset signal, switching, via the control circuit, the relay from the OFF state to the ON state, wherein the relay allows power flow from the power input terminal through the relay in the ON state and prevents power flow from the power input terminal through the relay in the OFF state.

13. The method according to claim 12, wherein determining whether the magnitude of the sensed power flow exceeds a power threshold comprises:
receiving, via a feedback control circuit of the control circuit, the magnitude of the sensed power flow from the feedback sensor;
amplifying, via the feedback control circuit, the magnitude of the sensed power flow;
determining, via the feedback control circuit, whether the amplified magnitude of the sensed power flow exceeds the power threshold.

14. The method according to claim 13, wherein generating, by the control circuit, the relay control signal comprises:
generating, via the feedback control circuit, the relay control signal based on the amplified magnitude of the sensed power flow exceeding the power threshold;
latching, via a latch of the control circuit, the relay control signal based on the amplified magnitude of the sensed power flow exceeding the power threshold; and
switching, via a relay control circuit of the control circuit, the relay from the ON state to the OFF state based on the latched relay control signal.

15. The method according to claim 12, wherein switching, via the control circuit, the relay from the OFF state to the ON state comprises:
latching, via a latch of the control circuit, the reset signal from the reset terminal; and
switching, via a relay control circuit of the control circuit, the relay from the OFF state to the ON state based on the latched reset signal.
